(19) United States
(12) Patent Application Publication
(10) Pub. No.: US 2021/0391150 A1
(43) Pub. Date: Dec. 16, 2021

(54) Plasma Source Configuration

(71) Applicant: Plasma-Therm LLC, St. Petersburg, FL (US)

(72) Inventors: Leslie Michael Lea, East Hagbourne (GB); Russell Westerman, Land O' Lakes, FL (US); Sarpangala Hariharakeshava Hegde, Fremont, CA (US); Edmond A. Richards, Spring Hill, FL (US)

(73) Assignee: Plasma-Therm LLC, St. Petersburg, FL (US)

(21) Appl. No.: 17/064,978

(22) Filed: Oct. 7, 2020

Related U.S. Application Data
(60) Provisional application No. 63/037,250, filed on Jun. 10, 2020.

(51) Int. Cl. H01J 37/32; H01L 21/67; C23C 16/44

(52) U.S. Cl. CPC H01J 37/32477; H01L 21/67069; H01J 2237/332; C23C 16/4401; H01J 2237/334; H01J 37/32082

(57) ABSTRACT

The present invention provides an improved plasma source configuration comprising a vacuum chamber having the source. A dielectric member is in communication with the vacuum chamber and surrounded by the plasma source. A high aspect ratio gap is formed between a film breaker and the dielectric member.

### CROSS REFERENCES TO RELATED APPLICATIONS

This application claims priority from and is related to commonly owned U.S. Provisional Patent Application Ser. No. 63/037,250 filed Jun. 10, 2020, entitled: Improved Plasma Source Configuration, this Provisional Patent Application incorporated by reference herein.

### FIELD OF THE INVENTION

Embodiments of the present invention relate to devices and methods for plasma processing in a vacuum chamber. More particularly, embodiments relate to devices and methods for shielding a power source during plasma processing.

### BACKGROUND OF THE INVENTION

Many plasma sources couple RF energy to the plasma through a dielectric window, e.g., Inductively Coupled Plasma (ICP), Transformer Coupled Plasma (TCP), Helicon Wave sources, Microwave, etc. into a vacuum chamber for plasma processing a semiconductor wafer. In certain types of vacuum chambers, the chamber walls may be formed of a conductive metal such as stainless steel. Because of the conductivity of the chamber walls, the RF coil is placed within the chamber itself because the conducting chamber walls would block or substantially attenuate the electromagnetic energy radiating from the coil. As a result, the coil may be directly exposed to the deposition flux and energetic plasma particles. To protect the coils, shields can be made from non-conducting ceramic materials. However, some plasma processes involve deposition of conductive materials such as aluminum on the electronic device being fabricated. Because the conductive material will coat the ceramic shield, the shield will become conducting, thus substantially attenuating the penetration of electromagnetic radiation into the plasma.

Conductive films can also be deposited during plasma etch processes. Ideally plasma etch processes result in volatile etch byproducts which can be exhausted from the vacuum chamber in the gas phase. Some etch processes can generate non-volatile etch byproducts. Consequently, some etch byproducts can be redeposited within the vacuum chamber. In some applications, the redeposited byproducts can form an electrically conductive film within the vacuum chamber. For example during SiC via formation, a patterned SiC substrate with a metal (e.g., patterned Ni) mask can be plasma etched using an SF₆/O₂ chemistry. While the SiC etch byproducts are typically volatile, at least a portion of the Ni mask material consumed during the plasma etch redeposits within the vacuum chamber forming a conductive film on the ceramic shield.

Whether as a result of a plasma deposition process or a plasma etch process, the deposited conductive material can buildup on the dielectric window and can interfere with coupling RF energy through the dielectric window into the plasma. This buildup of conductive material deposited on the dielectric window can allow the formation of an eddy current within the conductive material. Eddy current flows counter to the direction of the electric field generated by the RF antenna. As a result, less electric field from the antenna is available to couple to the plasma which can reduce plasma density and can shift process results.

To inhibit the buildup of conductive material deposited on the dielectric window, the prior art used a structure within the plasma chamber to inhibit the formation of a continuous conductive material on the dielectric window. Specifically, a high aspect ratio (HAR) trench structure (film breaker) on/within the dielectric window. The HAR structure inhibits the conductive material from forming a continuous layer on the dielectric window by inhibiting the conductive material from forming a continuous conductive material across the film breaker surface. The HAR structure spans the dielectric window where it overlaps the antenna and the HAR structure significantly reduces the ability of the conductive material to deposit at the bottom of the HAR structure.

However, the conductive material deposited on the HAR structure on the film breaker builds up over time. Eventually, with enough time, a continuous conductive material can be formed in the HAR feature. Once the coating across the film breaker is continuous, the benefit of the film breaker is greatly reduced. At this point, the HAR structure needs to be reworked, cleaned or replaced to recover the benefit of the film breaker. In order to recover the film breaker effectiveness, the conductive material must be removed from at least a portion of the HAR structure of the film breaker. Preferably, the conductive material is completely removed from the HAR structure of the film breaker.

While HAR features are preferred to inhibit deposition from reaching the bottom of the feature, they also make the HAR feature difficult to clean (e.g., difficult to remove the conductive material from the bottom of the HAR feature). The prior art provides for physical removal of the conductive material from the bottom of the HAR feature through bead blasting, ultrasonics, chemicals, etc. However, these methods can be difficult and time consuming.

Therefore, it is an object of the present invention to provide an apparatus and method that addresses the limitation of previous HAR features and which is a significant contribution to the advancement of charged particle sources.

Nothing in the prior art provides the benefits attendant with the present invention.

Another object of the present invention is to provide an improved plasma source configuration, comprising: a vacuum chamber having a plasma source for generating a plasma therein; a dielectric window in communication with the vacuum chamber; a film breaker disposed within the vacuum chamber; and a high aspect ratio gap formed between said film breaker and the dielectric window.

Yet another object of the present invention is to provide an improved plasma source configuration, comprising: a vacuum chamber having a plasma source for generating a plasma therein; a dielectric window in communication with the vacuum chamber; a film breaker disposed within the vacuum chamber, said film breaker having at least two components; and a high aspect ratio gap formed between the at least two components of said film breaker.

Still yet another object of the present invention is to provide a method for processing a substrate in a plasma processing system, the method comprising: generating a plasma within a vacuum chamber using a plasma source, the vacuum chamber having a dielectric window surrounded by the plasma source; providing a film breaker disposed within the vacuum chamber; processing the substrate within the vacuum chamber; and inhibiting the deposition of a thin film onto a portion of the dielectric window using said film breaker.

The foregoing has outlined some of the pertinent objects of the present invention. These objects should be construed to be merely illustrative of some of the more prominent features and applications of the intended invention. Many other beneficial results can be attained by applying the disclosed invention in a different manner or modifying the invention within the scope of the disclosure. Accordingly, other objects and a fuller understanding of the invention may be had by referring to the summary of the invention and the detailed description of the preferred embodiment in addition to the scope of the invention defined by the claims taken in conjunction with the accompanying drawings.

### SUMMARY OF THE INVENTION

Another feature of the present invention is to provide an improved plasma source configuration comprising a vacuum chamber having a plasma source for generating a plasma therein. A dielectric window is in communication with the vacuum chamber. A film breaker is disposed within the vacuum chamber. In one embodiment, a gas inlet can be positioned within the film breaker. A high aspect ratio gap is formed between the film breaker and the dielectric window. The film breaker can further comprise a dielectric material or a conductive material or a combination of dielectric and conductive materials. A plurality of film breakers can be disposed within the vacuum chamber. An antenna can be positioned adjacent to the dielectric window wherein the film breaker intersects the antenna (e.g., in the case where the antenna is located external to the vacuum chamber, the dielectric window is positioned between the antenna and the film breaker—the film breaker is located within the vacuum chamber). A portion of the film breaker can overlap the dielectric window wherein the overlapping portion of the film breaker is not in contact with the dielectric window.

Yet another feature of the present invention is to provide an improved plasma source configuration, comprising a vacuum chamber having a plasma source for generating a plasma therein. A dielectric window is in communication with the vacuum chamber. A film breaker is disposed within the vacuum chamber. The film breaker has at least two components wherein a at least a portion of a high aspect ratio gap is formed between the at least two components of the film breaker. The film breaker can further comprise a dielectric material or a conductive material or a combination of dielectric and conductive materials. The plasma processing system can further comprise a plurality of film breakers. An antenna can be positioned adjacent to the dielectric window wherein the film breaker intersects the antenna. The antenna can be external to the vacuum chamber. A portion of the film breaker can overlap the dielectric window wherein the overlapping portion of the film breaker is not in contact with the dielectric window. A gas inlet can be positioned within the film breaker.

Still yet another feature of the present invention is to provide a method for processing a substrate in a plasma processing system, the method comprising the following steps. A plasma is generated within a vacuum chamber using a plasma source. The vacuum chamber has a dielectric window surrounded by the plasma source. A film breaker is disposed within the vacuum chamber. The substrate is processed within the vacuum chamber. The deposition of a thin film is inhibited from depositing onto a portion of the dielectric window using the film breaker. The processing of the substrate can further comprise the depositing of a material onto the substrate. The processing of the substrate can further comprise the etching of a material from the substrate. The processing of the substrate can further comprise the etching of SiC from the substrate. The film breaker can further comprise a dielectric material or a conductive material. The plasma processing system can further comprise a plurality of film breakers. An antenna can be positioned adjacent to the dielectric window wherein the film breaker intersects the antenna. A portion of the film breaker can overlap the dielectric window wherein the overlapping portion of the film breaker is not in contact with the dielectric window. A gas can be injected into a gap between the film breaker and the dielectric window.

The foregoing has outlined rather broadly the more pertinent and important features of the present invention in order that the detailed description of the invention that follows may be better understood so that the present contribution to the art can be more fully appreciated. Additional features of the invention will be described hereinafter which form the subject of the claims of the invention. It should be appreciated by those skilled in the art that the conception and the specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

FIG. 1 (Prior art) is a schematic view showing a plasma vacuum chamber with an ICP source;

FIG. 2 (Prior art) is a schematic view showing a plasma vacuum chamber with a TCP source;

FIG. 3 (Prior art) is a schematic view showing a plasma vacuum chamber with a high-density ICP source;

FIG. 4A (prior art) is a blown up view showing an ICP source with a prior art film breaker;

FIG. 4B (prior art) is a top view of a plasma source dielectric window with a prior art film breaker;

FIG. 5A is a top view of a plasma source with an improved film breaker according to one embodiment of the present invention;

FIG. 5B is a detailed top view of a plasma source dielectric window with an improved film breaker according to one embodiment of the present invention;

FIG. 6A is a cross sectional view of a plasma source with a film breaker with a variable width gap (the film breaker is in contact with the dielectric window) according to one embodiment of the present invention;

FIG. 6B is a cross sectional view of a plasma source with a film breaker with a variable width gap (the film breaker does not contact the dielectric window) according to one embodiment of the present invention;

FIG. 7A is a cross sectional view of a plasma source with an improved film breaker according to one embodiment of the present invention;

FIG. 7B is a detailed view of an improved film breaker according to one embodiment of the present invention;

FIG. 8A is a cross sectional view of a plasma source with an improved film breaker according to one embodiment of the present invention;

FIG. 8B is a detailed view of an improved film breaker according to one embodiment of the present invention;

FIG. 9A is a top view of a multicomponent film breaker on a plasma source dielectric window according to one embodiment of the present invention;

FIG. 9B is a top view of a multicomponent film breaker where a gap is not defined by a dielectric window according to one embodiment of the present invention;

FIG. 10A is a top view of a TCP source with an improved film breaker according to one embodiment of the present invention;

FIG. 10B is a cross sectional view of TCP source with an improved film breaker according to one embodiment of the present invention;

FIG. 11A is a top view of an ICP source with an improved film breaker according to one embodiment of the present invention;

FIG. 11B is a cross sectional view of an ICP source with an improved film breaker according to one embodiment of the present invention;

FIG. 12A is a top view of a dielectric window and an installed improved film breaker coated with a conductive material from a deposition process according to one embodiment of the present invention; and

FIG. 12B is a top view of a dielectric window and a disassembled film breaker after being coated with a conductive material from a deposition process (assembly more easily cleaned once disassembled) according to one embodiment of the present invention.

Similar reference characters refer to similar parts throughout the several views of the drawings.

### DETAILED DESCRIPTION OF THE INVENTION

The present invention, according to one embodiment, provides a HAR film breaker wherein the HAR feature is formed by at least two components. These at least two components are sufficient to inhibit conductive material deposition in the HAR feature during the deposition of a thin film. When cleaning of the HAR film breaker is required, the HAR feature can be disassembled which provides for easy access to the interior surfaces of the HAR feature for the cleaning process. Thus, the manufacture of film breaker structures with very high aspect ratios (>10:1) according to the present invention allows for an easy to clean and maintain HAR film breaker.

In addition, the at least two components design is simpler to manufacture and reduces the cost of manufacturing the film breaker. Further, only a portion of the HAR surface is required to be electrically insulating. However, all of the HAR surfaces can be electrically insulating. The film breaker can contain conductive material (e.g. metal) components as well.

Using the design of the present invention, there is no need to machine high aspect ratio feature(s) into the film breaker. A low aspect ratio “step” on at least one part of the film breaker can be sufficient to form a HAR feature in the assembled film breaker structure.

The at least two components design of the present invention allows for more complex film breaker designs, e.g., HAR feature can be non-linear, HAR feature can be curved, HAR feature can include discontinuities.

The present invention is designed to minimize the effect of deposition of conductive material within the plasma source while providing a solution that is easy to maintain by creating a high aspect ratio (HAR) gap that inhibits continuous conductive material formation on the dielectric window. In one embodiment of the present invention, the HAR gap is formed between the film breaker and the dielectric window. A portion of the HAR gap can be formed within a multi-piece film breaker. The film breaker may contain more than one HAR gap. In another embodiment of the present invention, the plasma source has more than one film breaker. In another embodiment with more than one plasma source at least one film breaker overlaps more than one plasma source.

When the film breaker is assembled and installed in the plasma source, the film breaker forms a high aspect ratio feature (e.g. gap between film breaker and dielectric window) that inhibits continuous deposition of a conductive material on the dielectric window. When the film breaker is disassembled for cleaning or maintenance, the inner surface(s) of the film breaker high aspect ratio feature are easily accessible for cleaning (e.g., there are not any high aspect ratio gaps that require cleaning once the film breaker is disassembled). In other words, the sidewalls and floor of the gap with deposited material are accessible for cleaning.

In another embodiment of the present invention, the film breaker forms a high aspect ratio gap between the film breaker and the dielectric window without contacting the dielectric window.

In another embodiment of the present invention, a very high aspect ratio film breaker having a very high aspect ratio gap (e.g., aspect ratio >20:1) can be economically constructed through the assembly of at least two components. Whereas, it can be prohibitively expensive to machine very HAR features into dielectric materials.

A film breaker using the inventive method can contain a conductive material which lowers the cost to manufacture (aluminum vs ceramic) or at least one portion of the HAR gap can contain a dielectric material.

The conductive material that is deposited on the dielectric window can be a reaction product of a process. The process can be a deposition process, an etch process, or a combination of etch and deposition processes. The process can utilize a plasma. The conductive material can contain a metal such as Ni, Al, Au, Cr, Pb, etc. The process can be a chemical process (e.g., HDPECVD, PECVD, PEALD, DRIE etch, etc.) and/or a physical process (e.g., PVD, IBD, HiPIMs, sputter etch, etc.).

The conductive material that is deposited on the dielectric window can be a reaction byproduct of an etch process. The etch process can be a plasma etch process.

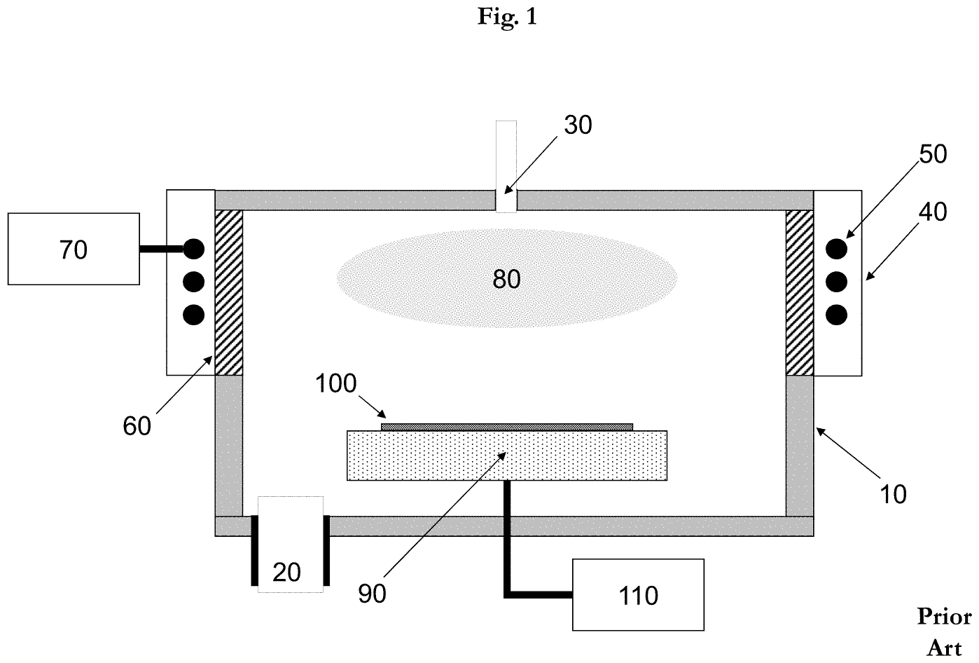

Prior art plasma reactors are shown in FIGS. 1, 2 and 3. A typical plasma system consists of a vacuum chamber (10) that is in communication with a vacuum exhaust (20) and a gas inlet (30). A plasma source (40) that has an antenna (50) used to couple an AC source (70) to the vacuum chamber (10) through a dielectric window (60) to form a plasma (80). The AC source (70) is typically an AC voltage source that has a frequency typically ranging from kHz to GHz. The AC source (70) can be an RF generator with a matching network (not shown) that can be used to minimize the impedance mismatch between the AC source (70) and the plasma (80) to improve power coupling from the AC source (70) to the plasma (80). A substrate support (90) can be located in the vacuum chamber (10) and the substrate support (90) can be connected to a voltage source (110) which is typically an AC voltage source with a frequency that typically ranges from kHz to GHz range. The AC voltage source can be an RF generator that can use a matching network (not shown) to minimize the impedance mismatch between the voltage source (110) and the substrate support (90). A substrate (100) can be located on the substrate support (90) wherein the substrate (100) can contain semiconductor devices that can consist of multiple components. The substrate (100) can be a wafer temporarily bonded to a processing carrier (not shown). The substrate (100) can contain semiconductor material, silicon, carbon and/or conducting material. The conducting material can be on an exposed surface of the substrate (100). The conducting material can be an etch mask on the substrate (100). The conducting material can be exposed to the plasma (80). The conducting material can be etched by the plasma (80). The conducting material can form at least one non-volatile byproduct which redeposits within the vacuum chamber (10). The substrate (100) can consist of a wafer mounted on tape mounted to a tape frame.

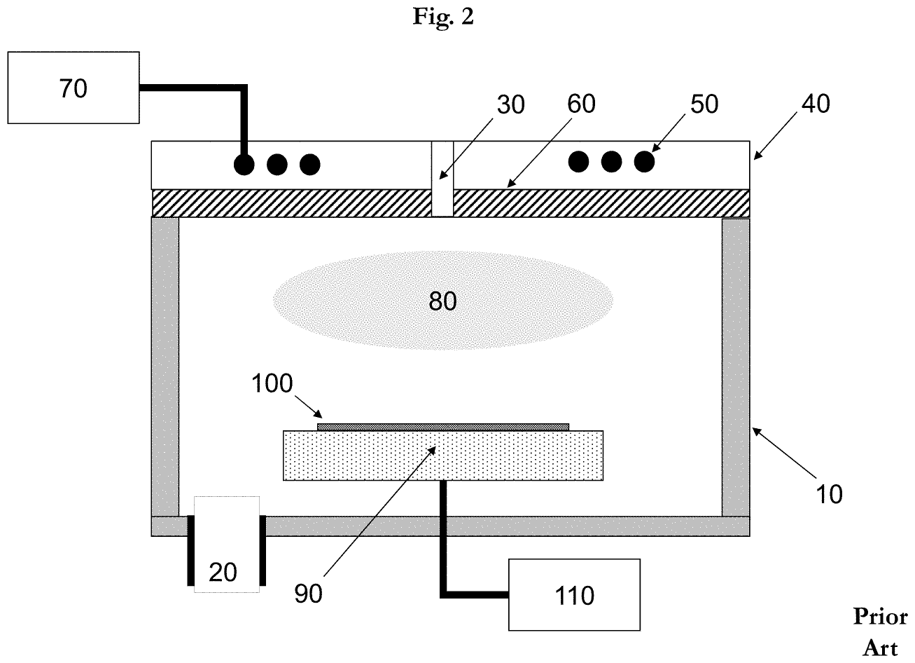

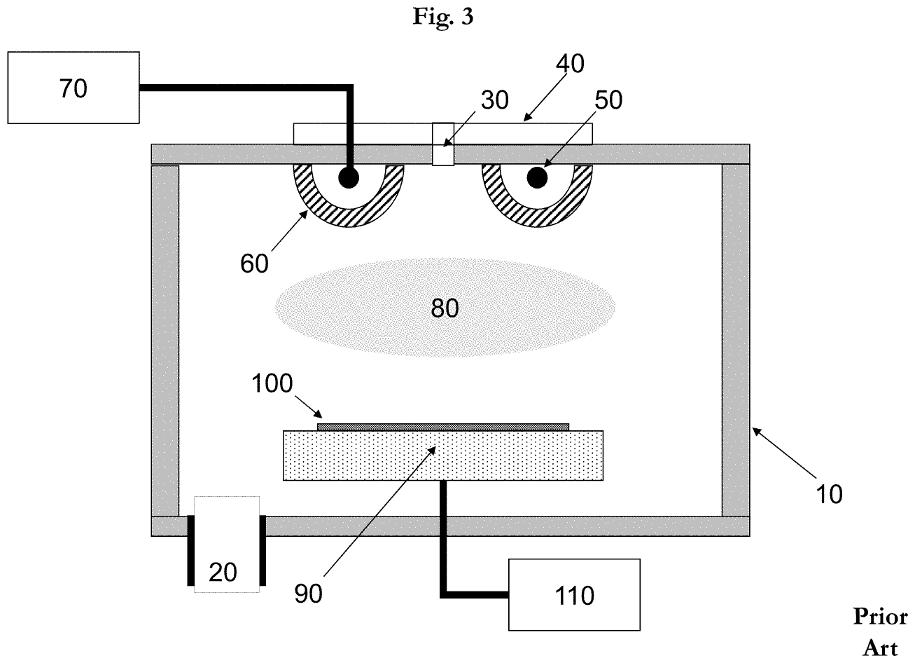

FIG. 1 shows a prior art helical inductively coupled plasma (ICP) reactor configuration. FIG. 2 shows a prior art transformer coupled plasma (TCP) reactor configuration. FIG. 3 shows an alternate prior art high-density plasma reactor configuration.

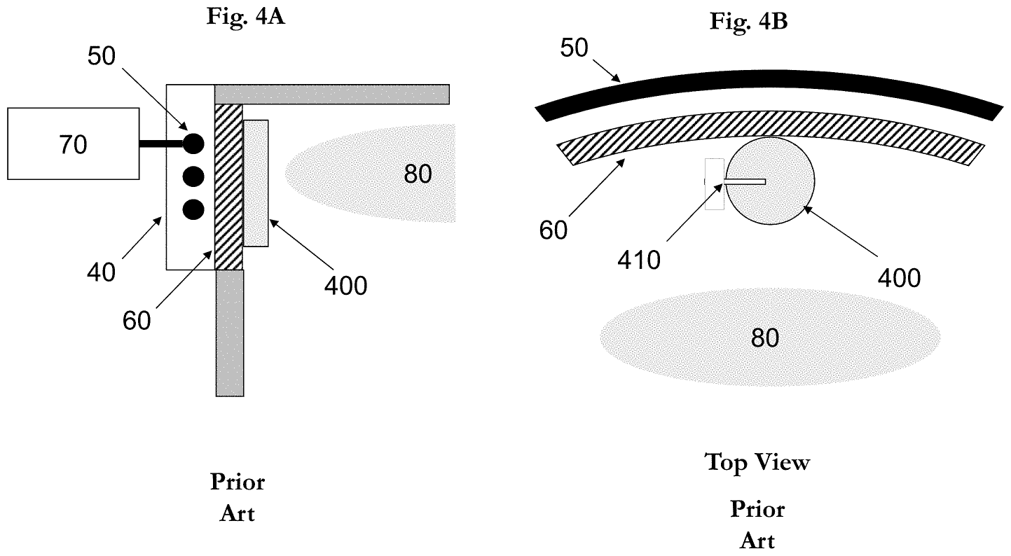

FIGS. 4A and 4B show prior art implementations of the use of a film breaker (400). Specifically, FIG. 4A (prior art) shows a film breaker (400) is placed in contact with the dielectric window (60) of an inductively coupled plasma source (40). FIG. 4B (prior art) shows a top view of a film breaker (400) in contact with a dielectric window (60). The Film breaker (400) is located on the vacuum side of dielectric window (60). The Film breaker (400) is in contact with plasma (80). The Film breaker (400) contains a high aspect ratio (HAR) trench (410). A deposition of conductive material from a process coats the exposed surfaces of the dielectric window (60) and the film breaker (400).

The width of the HAR trench (410) of the prior art is typically about 0.5 mm. The depth of the HAR trench (410) is typically a few millimeters. A conductive material may deposit within the HAR trench (410). The high aspect ratio of the trench minimizes the deposition from forming a conductive material across the bottom of the gap.

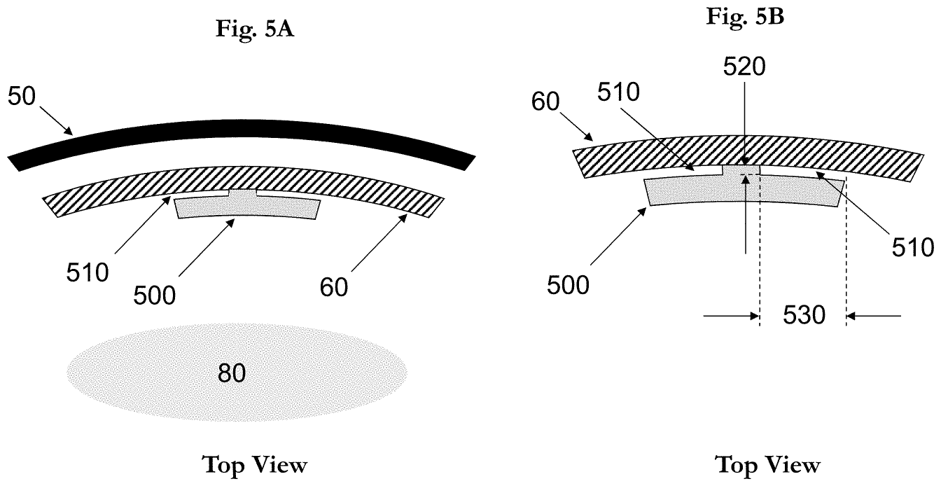

FIGS. 5A and 5B show embodiments according to the present invention. According to one embodiment of the present invention, the film breaker (500) contains a dielectric material. According to one embodiment of the present invention, the film breaker (500) contains a conductor. According to one embodiment of the present invention, the film breaker (500) contains a metal (e.g., aluminum). According to one embodiment of the present invention, the film breaker (500) contains a semiconductor. In one embodiment, a portion of the film breaker (500) is in contact with a dielectric window (60) wherein the portion of the film breaker (500) in contact with the dielectric window (60) intersects an antenna (not shown). In another embodiment, a portion of the film breaker (500) is in contact with the dielectric window (60) and completely intersects the coil (not shown). In all embodiments, the film breaker (500) contacts the dielectric window (60) around a plasma (80) facing a surface of the dielectric window (60). In another embodiment, the film breaker (500) contacts at least a portion of a surface of the dielectric window (60) that overlaps a portion of the antenna (not shown). In another embodiment, a portion of the film breaker (500) overlapping the dielectric window (60) is not in contact with the dielectric window (60). In all embodiments, at least one gap (510) is formed between a portion of the film breaker (500) and the dielectric window (60). As shown in FIGS. 5A and 5B, in another embodiment of the present invention, a gap (510) has a gap width (520) that is constant along a gap length (530).

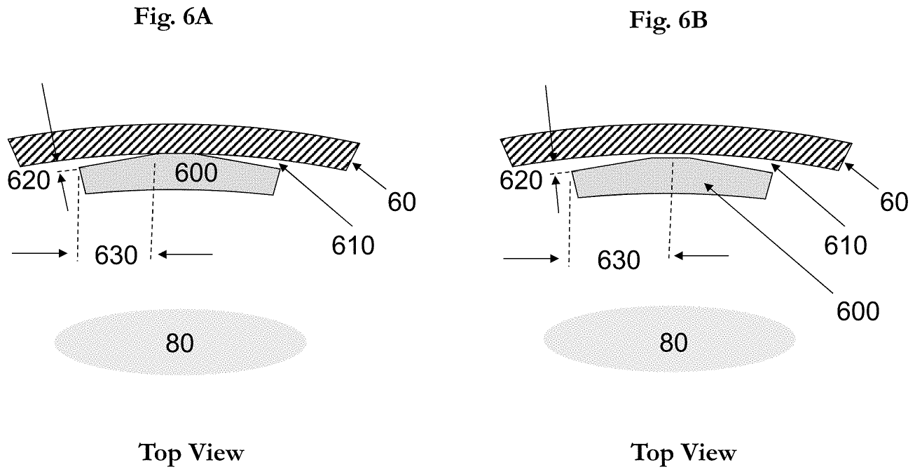

As shown in FIGS. 6A and 6B, in another embodiment of the present invention, a gap (610) has a gap width (620) that varies along at least a portion of a gap length (630). The gap width (620) can vary along the entire gap length (630). A gap aspect ratio of the gap (610) is the gap length (630) divided by the gap width (620). In another embodiment of the present invention, the gap (610) walls are parallel in at least a portion of the gap length (630). In another embodiment of the present invention, the gap (610) walls are parallel along the entire gap length (630). In another embodiment of the present invention, the gap width (620) varies along the gap length (630). In another embodiment of the present invention, the gap width (620) is less than 10 mm. In another embodiment of the present invention, the gap width (620) is less than 5 mm. In another embodiment of the present invention, the gap width (620) is less than 1 mm. In another embodiment of the present invention, the gap width (620) is less than 0.5 mm. In another embodiment of the present invention, the gap width (620) is less than 0.2 mm. In another embodiment, the gap aspect ratio is greater than 1:1. In another embodiment, the gap aspect ratio is greater than 5:1. In another embodiment, the gap aspect ratio is greater than 10:1. In another embodiment, the gap aspect ratio is greater than 20:1. In another embodiment, the gap (610) is formed between the film breaker (600) and the dielectric window (60). In another embodiment, the gap (610) overlaps the antenna (not shown). In another embodiment, the gap width (620) is non-constant along a gap length (630). In another embodiment, the gap (610) sidewalls are not parallel in at least a portion of the gap (610). In another embodiment, the gap (610) sidewalls are not parallel in any portion of the gap (610). In another embodiment, the gap width (620) is wider where the gap is closer to the plasma (80). The wider gap width (620) is near the plasma helps inhibit deposition from the process from closing off the gap (620) at the entrance of the gap (610).

As shown in FIG. 6A, according to one embodiment of the present invention, a portion of the film breaker (600) can be in contact with the dielectric window (60).

As shown in FIG. 6B, according to one embodiment of the present invention, the film breaker (600) overlaps the dielectric window (60) but may not be in contact with the dielectric window (60).

In all embodiments, it is preferred that the gap contain a HAR region to minimize conductive material deposition within the gap. HAR can be defined as gap length divided by the gap width. In another embodiment, it is preferred that the gap has an aspect ratio >5:1. In another embodiment, it is preferred that the gap has an aspect ratio >10:1. In another embodiment, it is preferred that the gap has an aspect ratio >20:1.

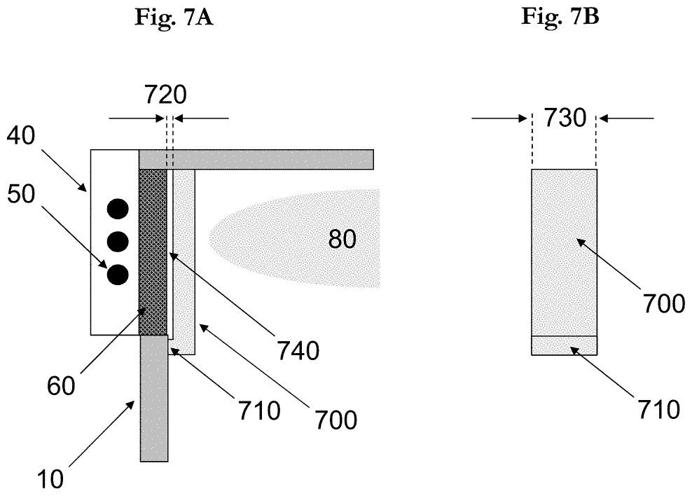

FIGS. 7A and 7B show embodiments of the present invention with an antenna (50), a dielectric window (60) adjacent to the antenna (50), a film breaker (700) that intersects the antenna (50). According to one embodiment of the present invention, the film breaker (700) completely intersects the antenna (50). According to one embodiment of the present invention, the film breaker (700) overlaps the dielectric window (60). According to one embodiment of the present invention, the film breaker (700) intersects the dielectric window (60). According to one embodiment of the present invention, the film breaker (700) completely intersects the dielectric window (60). According to all embodiments of the present invention, a gap (740) is formed between the film breaker (700) and the dielectric window (60). According to one embodiment of the present invention, the film breaker (700) does not contact dielectric window (60). According to one embodiment of the present invention, the film breaker (700) contains at least one support (710). According to one embodiment of the present invention, the support (710) contacts the vacuum chamber (10). According to one embodiment of the present invention, the support (710) is attached to the vacuum chamber (10). According to one embodiment of the present invention, the support (710) defines a gap distance (720) between the film breaker (700) and the dielectric window (60). The aspect ratio of the gap (740) is defined as a film breaker width (730) divided by a distance (720) between the film breaker (700) and the dielectric window (60). In the case where at least two opposing sides of the gap (740) are exposed to the plasma (80), the effective gap aspect ratio can be ½ the calculated aspect ratio since deposition of the conductive material may enter the gap (740) from multiple sides.

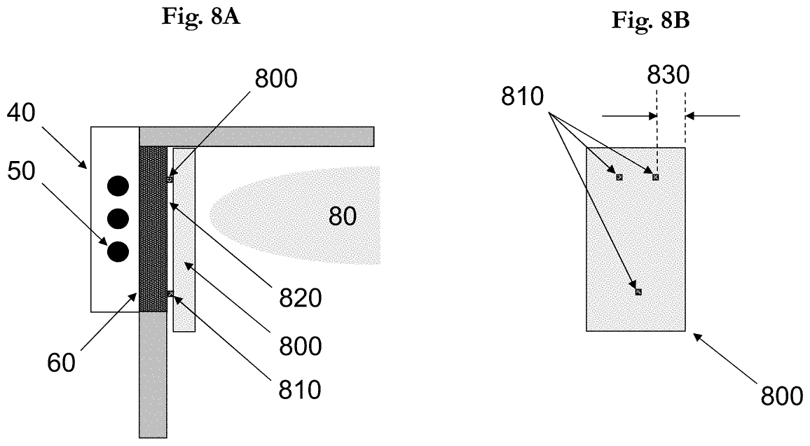

FIGS. 8A and 8B show embodiments of the present invention with an antenna (50), a dielectric window (60) that is adjacent to the antenna (50), a film breaker (800), a gap (820) between the film breaker (800) and the dielectric window (60). According to one embodiment of the present invention, the gap (820) is defined by at least one film breaker support (810). According to one embodiment of the present invention, a film breaker support (810) is attached to the film breaker (800). According to one embodiment of the present invention, a film breaker support (810) is attached to the dielectric window (60). According to one embodiment of the present invention, the gap (820) is defined by more than one film breaker support (810). According to one embodiment of the present invention, the gap (820) is defined by three film breaker supports (810). According to one embodiment of the present invention, at least two film breaker supports (810) are identical. According to one embodiment of the present invention, the film breaker supports (810) are identical height. According to one embodiment of the present invention, the film breaker supports (810) are identical shape. According to one embodiment of the present invention, at least two film breaker supports (810) are different in height and/or shape. According to one embodiment of the present invention, the aspect ratio of the gap (800) is defined by gap length (830) divided by gap width (820). According to one embodiment of the present invention, the effective gap length (830) is a minimum distance from the film breaker support (810) to the plasma-exposed edge of the gap (800). According to one embodiment of the present invention, the effective gap (800) is greater than 1:1. According to one embodiment of the present invention, the effective gap (800) is greater than 5:1. According to one embodiment of the present invention, the effective gap (800) is greater than 10:1. According to one embodiment of the present invention, the effective gap (800) is greater than 20:1.

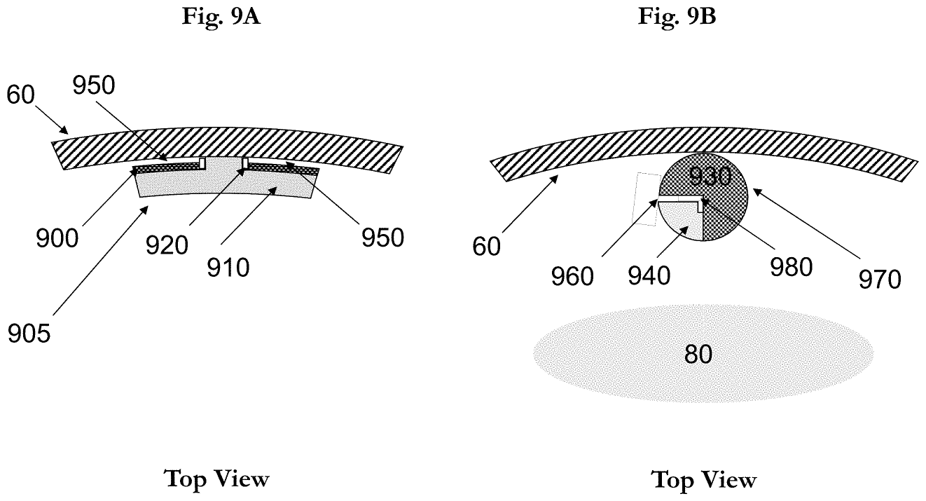

FIG. 9A shows one embodiment of the present invention with a dielectric window (60) that is adjacent to an antenna (not shown), a film breaker (905) that consists of at least two components. According to one embodiment of the present invention, the film breaker (905) consists of more than one material. According to one embodiment of the present invention, the film breaker (905) has at least one conductive part. According to one embodiment of the present invention, a portion of a gap (950) is defined by the film breaker (905) and the dielectric window (60). According to one embodiment of the present invention, the gap (950) can contain a discontinuity (920). According to one embodiment of the present invention, the discontinuity (920) is not co-linear with the gap (950). According to one embodiment of the present invention, the discontinuity (920) is perpendicular to the gap (950). According to one embodiment of the present invention, at least a portion of the gap (950) is defined by two components (910 and 920) of the film breaker (905).

FIG. 9B shows one embodiment of the present invention with a film breaker (970) wherein a portion of at least one gap (960) is defined by at least two components (930 and 940) of the film breaker (970). According to one embodiment of the present invention, at least one gap (960) is formed without a portion of the gap (960) being defined by the dielectric window (60). According to one embodiment of the present invention, the film breaker (970) overlaps the dielectric window (60). According to one embodiment of the present invention, the film breaker (970) is in contact with the dielectric window (60). According to one embodiment of the present invention, the gap (960) contains a discontinuity (980). According to one embodiment of the present invention, the discontinuity (980) is not co-linear with the gap (960). According to one embodiment of the present invention, the discontinuity (980) is perpendicular to the gap (960). According to one embodiment of the present invention, at least a portion of the gap (960) is defined by two components (930 and 940) of the film breaker (970).

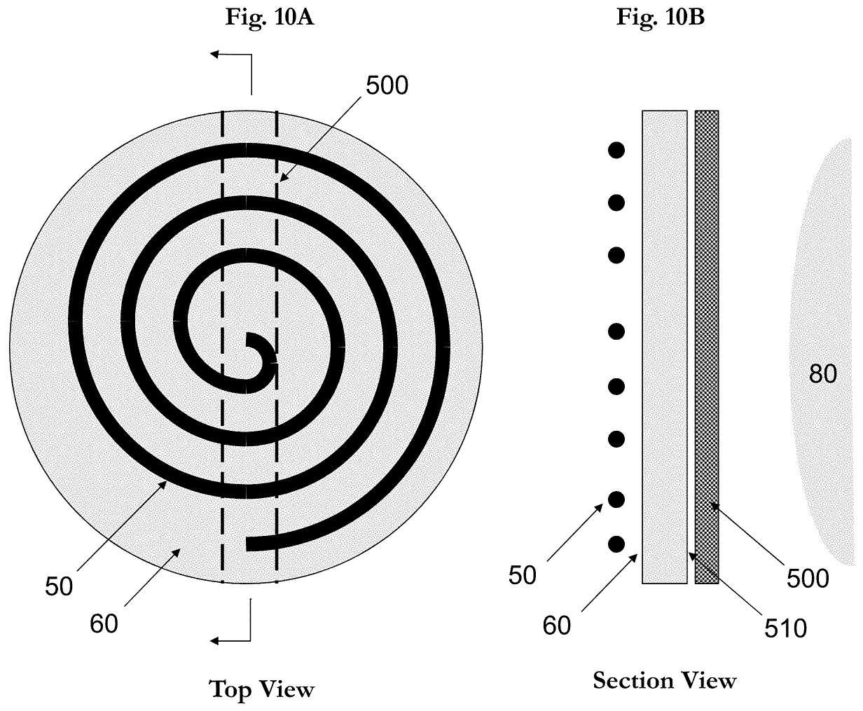

FIG. 10A shows one embodiment of the present invention with a film breaker (500) applied to a TCP (50). Note that while FIG. 10A shows the film breaker (500) overlapping the diameter of the TCP (50), it is sufficient for the film breaker (500) to overlap a radius of the TCP (50). FIG. 10B shows a cross section of the TCP (50) source and the film breaker (500) of FIG. 10A.

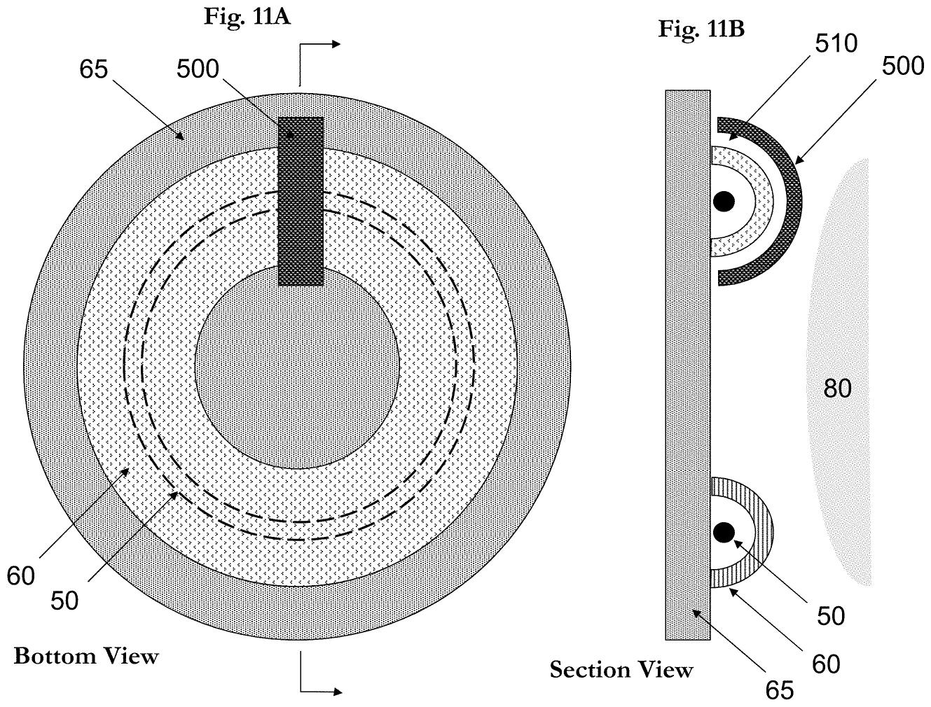

FIG. 11A shows one embodiment of the present invention with a film breaker (500) applied to a high-density inductive plasma source (50). FIG. 11B shows a cross section of the source (50) and film breaker (500) of FIG. 11A.

The dielectric window (60) can take a range of shapes, including but not limited to, planar, cylindrical, conical, domed, etc.

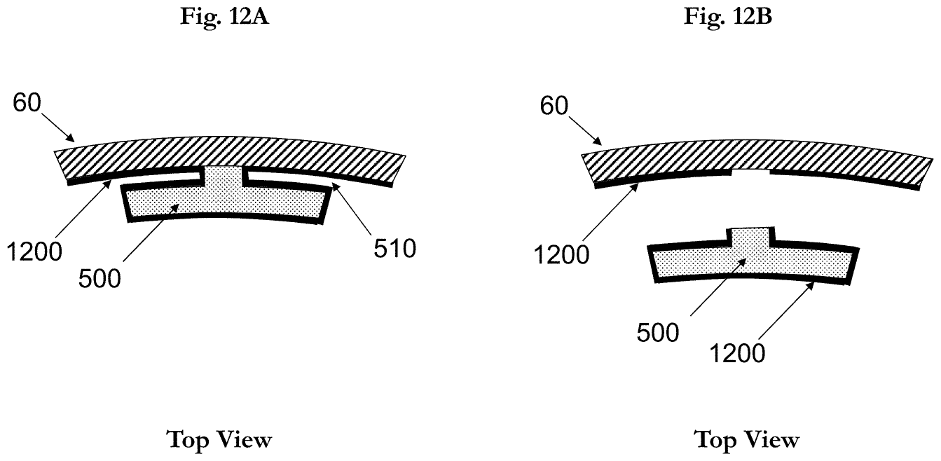

FIG. 12A shows one embodiment of the present invention with a film breaker (500) installed on a dielectric window (60). The installed film breaker (500) contains a high aspect ratio gap (510) which is formed between the film breaker (500) and the dielectric window (60). According to one embodiment of the present invention, the HAR gap (510) is formed within the film breaker (500). A conductive material (1200) has been deposited on the film breaker (500) and the dielectric window (60). The conductive material (1200) forms an electrically continuous film within the HAR gap (510) over time (e.g., conductive material generated during a process depositing in the plasma source (e.g., the dielectric window and film breaker).

FIG. 12B shows one embodiment of the present invention with a film breaker (500) that has been removed from a dielectric window (60) after being coated with a conductive material (1200). Note that the surfaces with the conductive material (1200) on the dielectric window (60) and the film breaker (500) are easily accessible for cleaning once the film breaker has been removed.

Cleaning of the surfaces of the film breaker and the dielectric window can be Physical cleaning (abrasive removal, bead blasting, etc.) and/or Chemical cleaning.

In all embodiments of the present invention, there can be more than one film breaker per plasma source. In all embodiments of the present invention, there can be more than one film breaker per dielectric window. In all embodiments of the present invention, there can be more than one film breaker per antenna. In all embodiments of the present invention, a film breaker can be applied to a source with more than one antenna. In all embodiments of the present invention, a film breaker can be applied to a plasma source with more than one dielectric window. In all embodiments of the present invention, a film breaker can be applied to plasma sources with more than one plasma generation zone. In all embodiments of the present invention, the film breaker can intersect the antenna. In all embodiments of the present invention, the film breaker can be perpendicular to the antenna.

In all embodiments of the present invention, a gas can be injected into the gap between the film breaker and the dielectric window. In all embodiments of the present invention, a gas can be ejected from a HAR gap formed by a film breaker. The ejected gas can originate from outside the process chamber (e.g. at least a portion of gas flow from outside the chamber can be introduced into the HAR gap and flow from the HAR gap into the process chamber). In all embodiments of the present invention, a gas can be ejected from a HAR gap formed within a film breaker. In all embodiments of the present invention, the gas inlet can be at edge of the film breaker. In all embodiments of the present invention, the gas inlet can be overlapped by the film breaker. In all embodiments of the present invention, the gas inlet can be completely overlapped by the film breaker. In all embodiments of the present invention, the gas inlet can be formed within the film breaker. In all embodiments of the present invention, the gas can contain an inert gas such as a noble gas (He, Ar, etc.). In all embodiments of the present invention, at least a portion of the antenna can be located within the plasma. In all embodiments of the present invention, the antenna can have a dielectric coating. In all embodiments of the present invention, the film breaker can overlap the antenna to inhibit the deposition on at least a portion of the antenna.

The present disclosure includes that contained in the appended claims, as well as that of the foregoing description. Although this invention has been described in its preferred form with a certain degree of particularity, it is understood that the present disclosure of the preferred form has been made only by way of example and that numerous changes in the details of construction and the combination and arrangement of parts may be resorted to without departing from the spirit and scope of the invention.

What is claimed is:

1. An improved plasma source configuration, comprising:
a vacuum chamber having a plasma source for generating a plasma therein;
a dielectric window in communication with the vacuum chamber;
a film breaker disposed within the vacuum chamber; and
a high aspect ratio gap formed between said film breaker and the dielectric window.

2. The plasma source configuration according to claim 1, wherein said film breaker further comprising a dielectric material.

3. The plasma source configuration according to claim 1, wherein said film breaker further comprising a conductive material.

4. The plasma source configuration according to claim 1, further comprising a plurality of film breakers.

5. The plasma source configuration according to claim 1, further comprising an antenna adjacent to the dielectric window, said film breaker intersects the antenna.

6. The plasma source configuration according to claim 1, wherein a portion of said film breaker overlaps the dielectric window, said overlapping portion of said film breaker is not in contact with the dielectric window.

7. The plasma source configuration according to claim 1, further comprising a gas inlet within said film breaker.

8. An improved plasma source configuration, comprising:
a vacuum chamber having a plasma source for generating a plasma therein;
a dielectric window in communication with the vacuum chamber;
a film breaker disposed within the vacuum chamber, said film breaker having at least two components; and
a high aspect ratio gap formed between the at least two components of said film breaker.

9. The plasma source configuration according to claim 8, wherein said film breaker further comprising a dielectric material.

10. The plasma source configuration according to claim 8, wherein said film breaker further comprising a conductive material.

11. The plasma source configuration according to claim 8, further comprising a plurality of film breakers.

12. The plasma source configuration according to claim 8, further comprising an antenna adjacent to the dielectric window, said film breaker intersects the antenna.

13. The plasma source configuration according to claim 8, wherein a portion of said film breaker overlaps the dielectric window, said overlapping portion of said film breaker is not in contact with the dielectric window.

14. The plasma source configuration according to claim 8, further comprising a gas inlet within said film breaker.

15. A method for processing a substrate in a plasma processing system, the method comprising:
generating a plasma within a vacuum chamber using a plasma source, the vacuum chamber having a dielectric window surrounded by the plasma source;
providing a film breaker disposed within the vacuum chamber;
processing the substrate within the vacuum chamber; and
inhibiting the deposition of a thin film onto a portion of the dielectric window using said film breaker.

16. The method according to claim 15, wherein the processing of the substrate further comprising depositing a material onto the substrate.

17. The method according to claim 15, wherein the processing of the substrate further comprising etching a material from the substrate.

18. The method according to claim 15, wherein the processing of the substrate further comprising etching SiC from the substrate.

19. The method according to claim 15, wherein said film breaker further comprising a dielectric material.

20. The method according to claim 15, wherein said film breaker further comprising a conductive material.

21. The method according to claim 15, further comprising a plurality of film breakers.

22. The method according to claim 15, further comprising an antenna adjacent to the dielectric window, said film breaker intersects the antenna.

23. The method according to claim 15, wherein a portion of said film breaker overlaps the dielectric window, said overlapping portion of said film breaker is not in contact with the dielectric window.

24. The method according to claim 15, further comprising injecting a gas into a gap between said film breaker and the dielectric window.
